(19) United States
(12) Patent Application Publication
(10) Pub. No.: US 2015/0096612 A1
(43) Pub. Date: Apr. 9, 2015

(54) BACK-CONTACT SOLAR CELL AND MANUFACTURING METHOD THEREOF

(71) Applicant: NEO SOLAR POWER CORP., HSINCHU CITY (TW)

(72) Inventors: SHAO-CHIN TSENG, HSINCHU CITY (TW); TIEN-SHAO CHUANG, HSINCHU CITY (TW); KUN-CHIH LIN, HSINCHU CITY (TW)

(21) Appl. No.: 14/491,163

(22) Filed: Sep. 19, 2014

(30) Foreign Application Priority Data
Oct. 9, 2013 (TW) 102136620

(51) Int. Cl. H01L 31/0224; H01L 31/0216; H01L 31/0236; H01L 31/18

(52) U.S. Cl. CPC H01L 31/022441; H01L 31/1868; H01L 31/02168; H01L 31/02363
USPC 136/256; 438/98

(57) ABSTRACT

A back-contact solar cell and manufacturing method thereof includes steps of providing a substrate, forming a first conductive doping region and a second conductive doping region on the substrate, forming a passivation layer on the substrate to cover the first conductive doping region and the second conductive doping region, distantly disposing a plurality of first electrode paste clusters on the passivation layer, in which each first electrode paste cluster corresponds to the first conductive doping region and the second conductive doping region and includes a metal component and a glass component, enclosing the first electrode paste cluster by a plurality of second electrode pastes, and heating at least the first electrode paste clusters to an predetermined temperature so that the metal component, the metal component and the passivation layer contacted by the first electrode paste clusters forms a plurality of contacting regions.

### CROSS-REFERENCES TO RELATED APPLICATIONS

This non-provisional application claims priority under 35 U.S.C. §119(a) on Patent Application No. 102136620 filed in Taiwan, R.O.C. on Oct. 9, 2013, the entire contents of which are hereby incorporated by reference.

### BACKGROUND

1. Technical Field

The disclosure relates to solar cell structure, and particularly to a back-contact solar cell and manufacturing method thereof.

2. Related Art

Energy is often the foundation for researching and developing innovative technologies. Different kinds of non-polluting energy have been gradually developed, as a result of attention paid to the need for environmental care and the problems caused by typical electricity suppliers (such as thermal power generation, nuclear, power generation, etc.). In comparison with other types of energy, solar energy possesses higher electricity generation efficiency and broader applicability; consequently, the development of different kinds of solar cells is pursued vigorously.

Among various kinds of solar cells, due to the electrodes of the back-contact solar cell being configured on the rear surface thereof, the back-contact solar cell has a larger area for receiving sunlight on the front surface thereof, and therefore has higher electricity generation efficiency.

Conventionally, laser opening technology is used to manufacture the electrodes of the back-contact solar cell; the manufacturing process is described here briefly. Firstly, gaps 99 corresponding to the N-type doping regions 93 and the P-type doping regions 94 of the solar cell, as shown in FIG. 1A, are formed by applying the laser beam on the passivation layer 92 disposed on the substrate 91 of the solar cell. Then sputter is applied to fill a mixed metal component into the gaps 99 and to form a seed layer 95 on the passivation layer 92, as shown in FIG. 1B, wherein the mixed metal component includes aluminum, titanium, tungsten and copper. Next, an anti-coating layer 96 is applied on the seed layer 95 by using screen printing technology, in which portions of the seed layer 95 corresponding to the gaps are exposed to the outside, as shown in FIG. 1C. Then copper-tin alloy 97 is applied on the seed layer 95 via electroplating, as shown in FIG. 1D. In this way, the anti-coating layer 96 is removed, as shown in FIG. 1E. Finally, portions of the seed layer 95 which are assembled with the copper-tin alloy 97 are removed, thereby completing the manufacturing of the electrodes of the back-contact solar cell, as shown in FIG. 1F.

However, during forming the gaps 99, the laser beam may damage the surfaces of the P-type doping regions 94 and the N-type doping regions 93, thereby reducing the electricity generation efficiency of the back-contact solar cell. Additionally, laser opening has a higher manufacturing cost, and is complex and time-consuming.

### SUMMARY

In view of this, the disclosure provides a back-contact solar cell and manufacturing method thereof. The manufacturing method for back-contact solar cell includes providing a substrate which includes a first surface and a second surface; forming a first conductive doping region and a second conductive doping region on the second surface of the substrate; forming a passivation layer on the second surface to cover the first conductive doping region and the second conductive doping region, wherein the passivation layer is selected from silicon nitride, silicon oxide, silicon oxynitride, aluminum oxide or combinations of dielectric materials; distantly disposing a plurality of first electrode paste clusters on the passivation layer, wherein each first electrode paste cluster is disposed on the first conductive doping region and the second conductive doping region correspondingly, each first electrode paste cluster includes a first metal component and a first glass component selected from the group consisting of bismuth glass and lead glass; enclosing the first electrode paste clusters by a second electrode paste; and heating the first electrode paste clusters and the second electrode paste to a predetermined temperature to form a plurality of contacting regions on the passivation layer, wherein the first electrode paste clusters and the second electrode paste form an electrode structure. Wherein, the step of heating the first electrode paste clusters and the second electrode paste to the predetermined temperature is provided for allowing the first metal component, the first glass component and the passivation layer contacted to the first electrode paste cluster to form the contacting region in the passivation layer, so that the electricity generated from the back-contact solar cell is collected and outputted by the electrode structure through the contacting region.

The disclosure further provides a manufacturing method for back-contact solar cell. The manufacturing method includes providing a substrate including a first surface and a second surface; forming a first conductive doping region and a second conductive doping region on the second surface; forming a passivation layer on the second surface to cover the first conductive doping region and the second conductive doping region, wherein the passivation layer is selected from silicon nitride, silicon oxide, silicon oxynitride, aluminum oxide or combinations of dielectric materials; distantly disposing a plurality of first electrode paste clusters on the passivation layer, wherein each first electrode paste cluster is disposed on the first conductive doping region and the second conductive doping region correspondingly, each first electrode paste cluster includes a first metal component and a first glass component selected from the group consisting of bismuth glass and lead glass; heating the first electrode paste clusters to a predetermined temperature to allow the first metal component, the first glass component and the passivation layer contacted to the first electrode paste clusters to mutually form a plurality of contacting regions in the passivation layer; enclosing the first electrode paste clusters by a second electrode paste; and heating the first electrode paste clusters and the second electrode paste to form an electrode structure.

As described previously, instead of applying the conventional laser opening technique to remove the passivation layer to form the electrode circuits for coating silver paste, the first electrode paste clusters are directly coated on the predefined positions to form the electrode, and then sintered to form the contacting regions. The contacting regions includes the metal component, the bismuth glass (or lead glass), and the passivation layer at the same time. The second electrode paste encloses the first electrode paste cluster and undergoes the sintering process along with the first electrode paste clusters before the contacting regions are formed; alternatively, the second electrode paste encloses the first electrode paste clusters after the contacting regions are formed.

Furthermore, the disclosure further provides a back-contact solar cell including a substrate, a passivation layer, a plurality of contacting regions and a plurality of electrode structures. The substrate includes a first surface and a second surface. The first surface is a light incident surface, and the second surface includes a first conductive doping region and a second conductive doping region. The passivation layer is disposed on the second surface to cover the first conductive doping region and the second conductive doping region. The contacting regions are disposed on the passivation layer distantly and each contact region corresponds to the first conductive doping region and the second conductive doping region. Each contacting region includes a metal component, a glass component and the passivation layer, wherein the glass component is selected from bismuth glass and lead glass, the passivation layer is selected from the group consisting of silicon nitride, silicon oxide, silicon oxynitride, aluminum oxide and combinations of dielectric materials.

Therefore, the contacting regions of the back-contact solar cell in accordance with the disclosure are not only made of metals; instead, the contacting regions includes the metal component, the bismuth glass (or lead glass), and passivation layer at the same time.

The detailed features and advantages of the disclosure are described below in great detail through the following embodiments. The content of the detailed description is sufficient for those skilled in the art to understand the technical content of the disclosure and to implement the disclosure there accordingly. Based on the content of the specification, the claims, and the drawings, those skilled in the art can easily understand the relevant objectives and advantages of the disclosure.

### BRIEF DESCRIPTION OF THE DRAWINGS

The disclosure will become more fully understood from the detailed description given herein below for illustration only, and thus not limitative of the disclosure, wherein:

FIG. 1A is a manufacturing scheme (1) of a conventional back-contact solar cell;

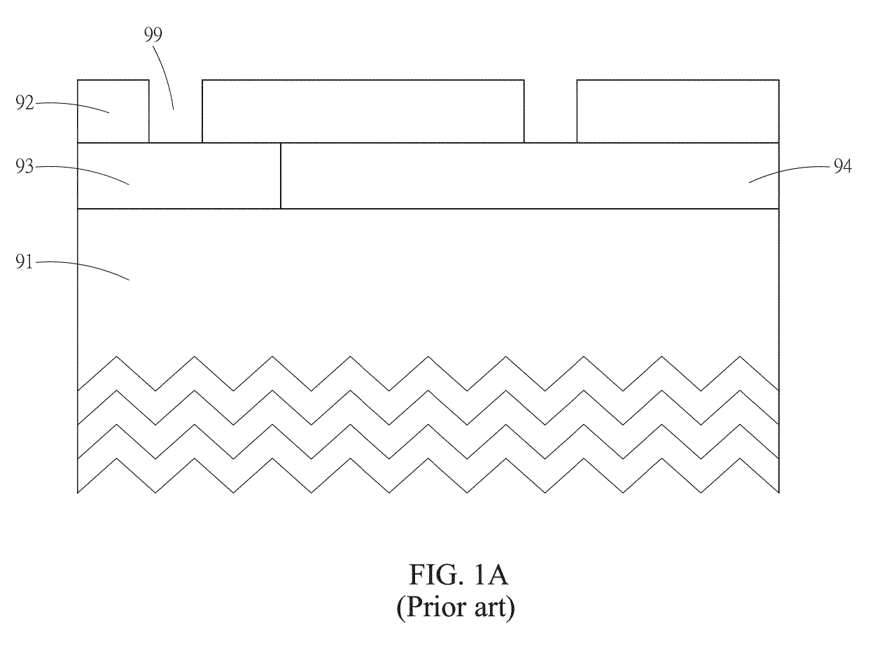

FIG. 1B is a manufacturing scheme (2) of the conventional back-contact solar cell;

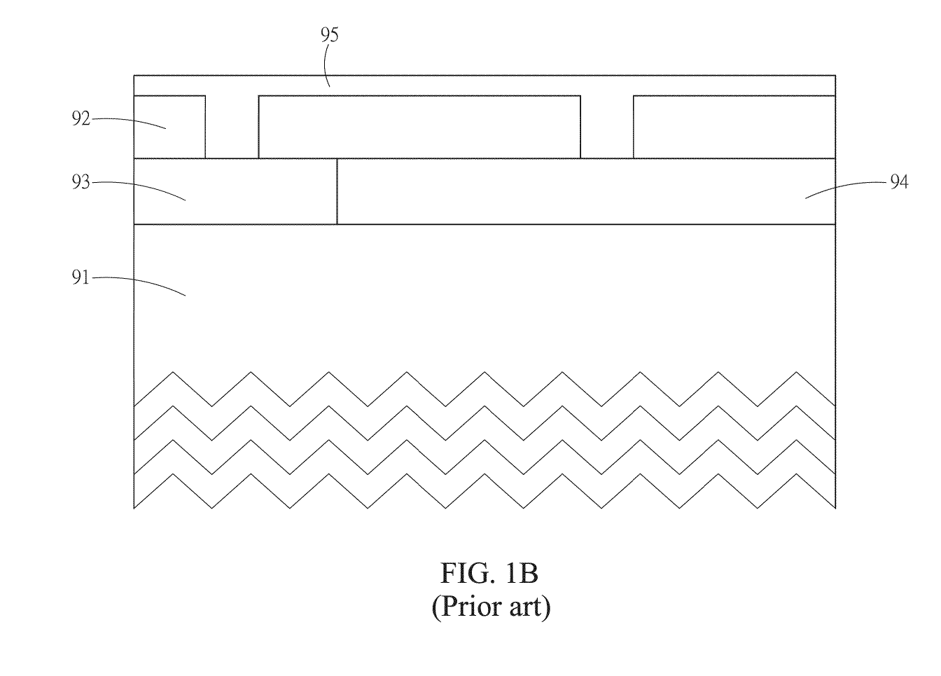

FIG. 1C is a manufacturing scheme (3) of the conventional back-contact solar cell;

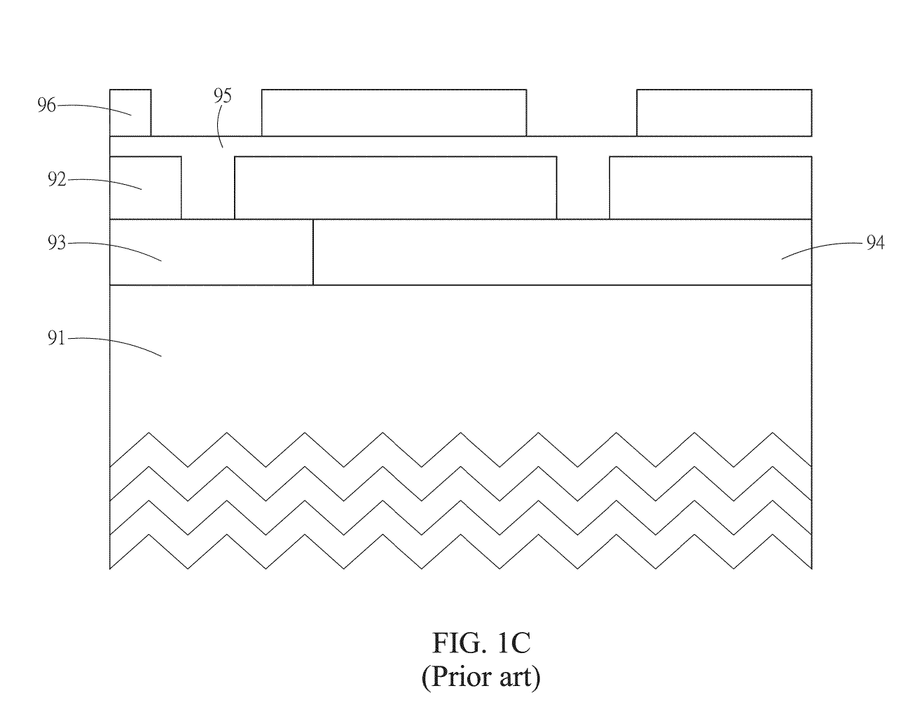

FIG. 1D is a manufacturing scheme (4) of the conventional back-contact solar cell;

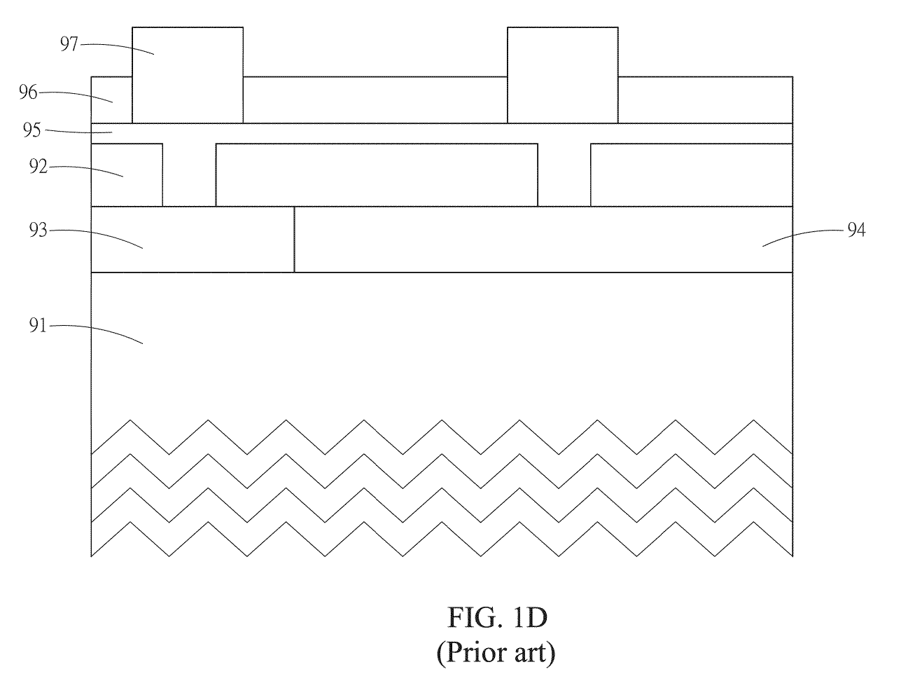

FIG. 1E is a manufacturing scheme (5) of the conventional back-contact solar cell;

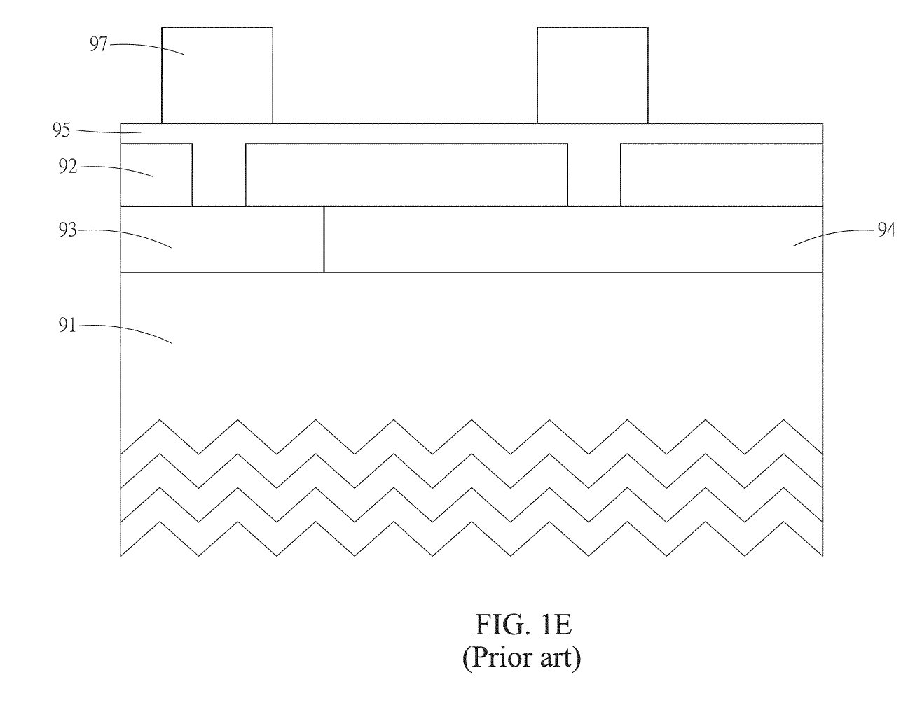

FIG. 1F is a manufacturing scheme (6) of the conventional back-contact solar cell;

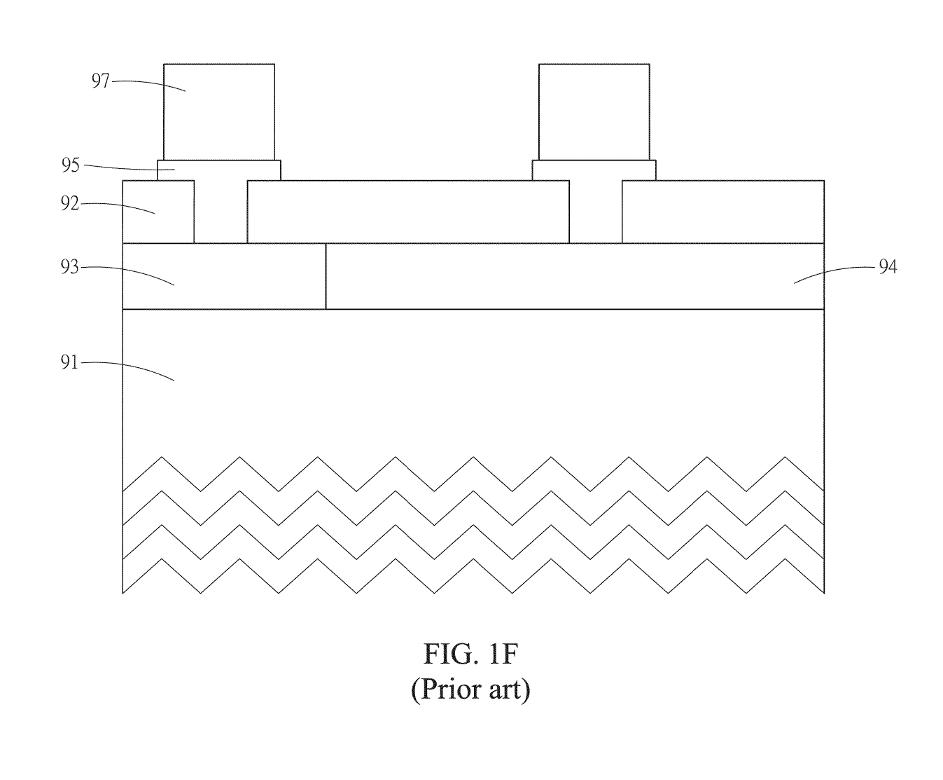

FIG. 2 is a flowchart for showing a manufacturing method for back-contact solar cell of a first embodiment of the disclosure;

FIG. 3A is a cross sectional view (1) of the back-contact solar cell in accordance with the disclosure;

FIG. 3B is a cross sectional view (2) of the back-contact solar cell in accordance with the disclosure;

FIG. 3C is a cross sectional view (3) of the back-contact solar cell in accordance with the disclosure;

FIG. 4A is an enlarged scanning electron microscope image for showing the first electrode paste clusters are disposed on the N-type doping region of the back-contact solar cell in accordance with the disclosure;

FIG. 4B is an enlarged scanning electron microscope image for showing the first electrode paste clusters and the second electrode paste are disposed on the N-type doping region of the back-contact solar cell in accordance with the disclosure;

FIG. 4C is an enlarged scanning electron microscope image for showing the first electrode paste clusters are disposed on the P-type doping region of the back-contact solar cell in accordance with the disclosure;

FIG. 4D is an enlarged scanning electron microscope image for showing the first electrode paste clusters and the second electrode paste are disposed on the P-type doping region of the back-contact solar cell in accordance with the disclosure; and

FIG. 5 is a flowchart for showing a manufacturing method for back-contact solar cell of a second embodiment of the disclosure.

### DETAILED DESCRIPTION

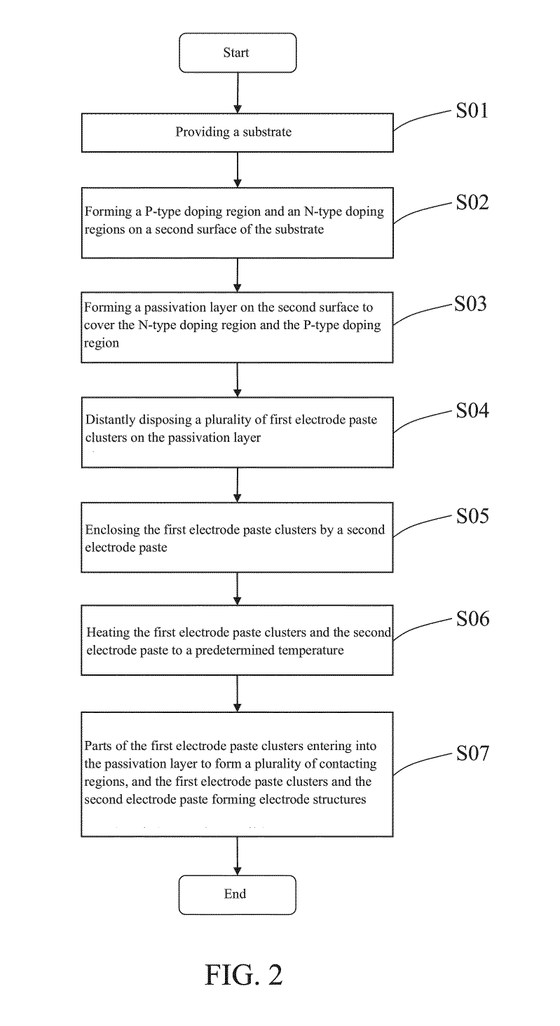

Please refer to FIG. 2, which illustrates a flowchart for showing a manufacturing method for back-contact solar cell of a first embodiment of the disclosure. The manufacturing method for back-contact solar cell includes following steps. Step S01: providing a substrate. Step S02: forming a P-type doping region and an N-type doping region on a second surface of the substrate. Step S03: forming a passivation layer on the second surface to cover the P-type doping region and the N-type doping region. Step S04: distantly disposing a plurality of first electrode paste clusters on the passivation layer. Step S05: enclosing the first electrode paste clusters by a second electrode paste. Step S06: heating the first electrode paste clusters and the second electrode paste to a predetermined temperature. Step S07: parts of the first electrode paste clusters entering into the passivation layer to form a plurality of contacting regions, and the first electrode paste clusters and the second electrode paste forming electrode structures. It is understood that although steps S01 to S07 proceed sequentially in the flowcharts, embodiments are not limited thereto.

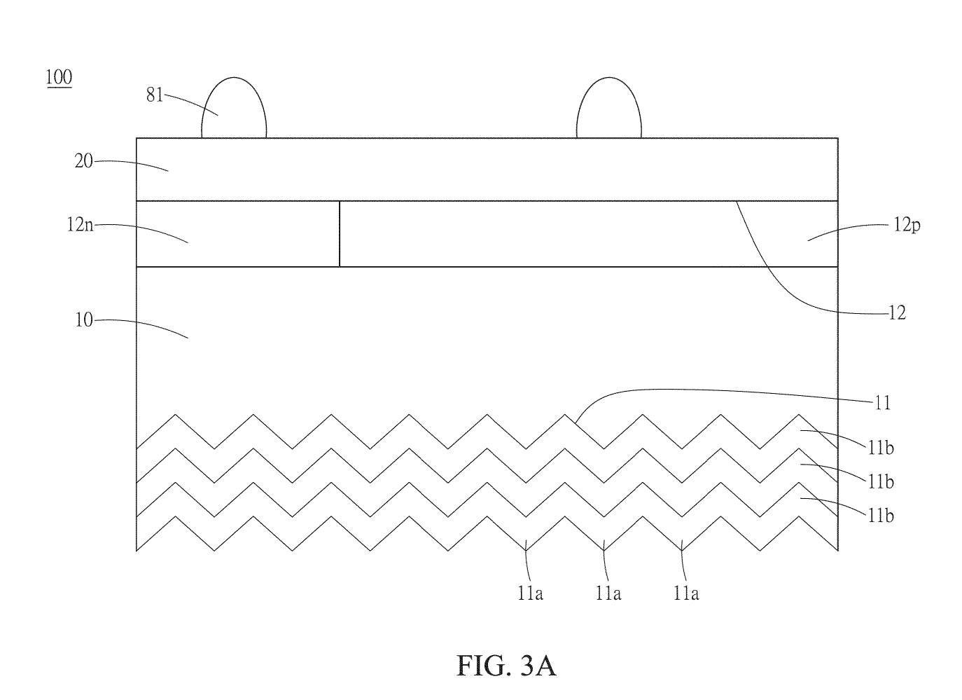

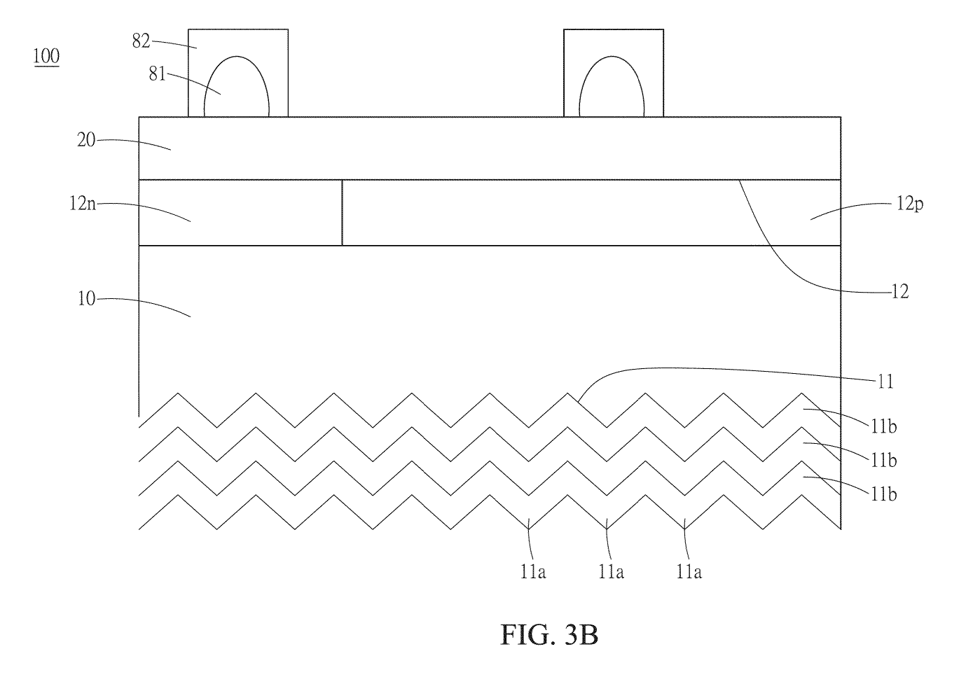

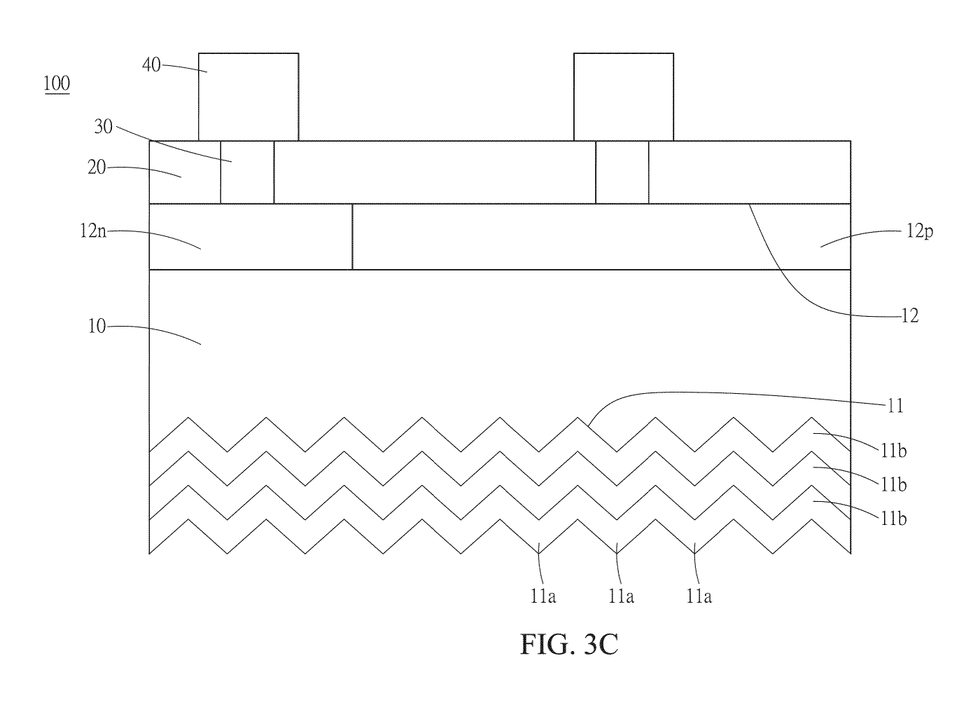

Please refer to FIG. 3A, in which embodiment step S01 is providing a substrate 10. Here, the substrate 10 is a semiconductor substrate for manufacturing a solar cell, and is manufactured from silicon water. The substrate 10 is an N-type silicon-based crystalline semiconductor substrate or a P-type silicon-based crystalline semiconductor substrate; here, the substrate 10 is the N-type silicon-based crystalline semiconductor substrate, but embodiments are not limited thereto. The N-type silicon-based crystalline semiconductor substrate is manufactured by mixing N-type dopants with the silicon wafer manufactured from floating zone method (FZ method), or Czochralski pulling technique (CZ pulling technique); while the P-type silicon-based crystalline semiconductor substrate is manufactured by mixing P-type dopants with the aforementioned silicon wafer. The substrate includes a first surface 11 and a second surface 12, wherein the first surface 11 is a light incident surface. As shown in FIG. 3A, the first surface 11 of the substrate 10 provided in step S01 already undergone a roughening process to form microstructures 11a thereon, and a plurality of anti-reflection layers 11b is formed on the first surface 11. The microstructures 11a reduce the reflectance of the incident light and provide a longer light path as compared to a flat surface, thereby increasing the light collecting efficiency of the first surface 11; for example, the microstructures 11a are arrays of well-aligned revered triangular pyramids. The anti-reflection layers 11b are provided for reducing the light loss caused by the light reflection.

Please refer to FIG. 2 and FIG. 3A, in which embodiment step S02 is forming P-type doping regions 12p and N-type doping regions 12n on the second surface 12 alternately. The majority carriers and the minority carriers of the P-type doping regions 12p are electron holes and electrons, respectively; while the majority carriers and the minority carriers of the N-type doping regions 12n are electrons and electron holes, respectively. Operating principles of the N-type doping regions 12n and the P-type doping regions 12p, and methods to form the P-type doping regions 12p or the N-type doping regions 12n on the second surface 12 is known by skilled in the arts so as not to be provided. In this embodiment, the thickness of the P-type doping regions 12p is equal to that of the N-type doping regions 12n, while the area of the P-type doping regions 12p is not equal to that of the N-type doping regions 12n, but embodiments are not limited thereto; in some implementation aspects, the area of the P-type doping regions 12p is equal to that of the N-type doping regions 12n, and the thickness of the P-type doping regions 12p is equal to or not equal to that of the N-type doping regions 12n. Furthermore, in this embodiment, the doping concentration of the P-type doping regions 12p is the same as that of the N-type doping regions 12n, but embodiments are not limited thereto. The doping concentration is one of the parameters for adjusting the photoelectric properties of the P-type doping regions 12p or N-type doping regions 12n. In this embodiment, the P-type doping regions 12p and the N-type doping regions 12n are parallel and alternately formed on the second surface 12.

Please refer to FIG. 3A, in which embodiment step S03 is forming a passivation layer 20 on the second surface 12 to cover the P-type doping regions 12p and the N-type doping regions 12n. The passivation layer 20 is provided mainly for reducing the surface carrier recombination velocity of the back-contact solar cell 100. The passivation layer 20 is selected from silicon nitride, silicon oxide, silicon oxynitride, aluminum oxide and combinations thereof, but embodiments are not limited thereto. In general, passivation layer 20 made from aluminum oxide is formed on the second surface 12 by using plasma enhanced chemical vapor deposition (PECVD), reactive sputtering or atomic layer deposition (ALD), but embodiments are not limited thereto; the passivation layer 20 can be formed on the second surface 12 via other means.

Please refer to FIG. 2 and FIG. 3A, in which embodiment step S04 is disposing a plurality of first electrode paste clusters 81 on the passivation layer 20 distantly; the first electrode paste clusters 81 corresponds to the N-type doping regions 12n and the P-type doping regions 12p. The first electrode paste clusters 81 are conductive and each first electrode paste cluster 81 includes a first metal component and a first glass component. The first metal component is selected from aluminum, silver, copper and combinations thereof. The first glass component is selected from bismuth glass or lead glass. In this embodiment, the first metal component of the first electrode paste clusters 81 disposed on the N-type doping regions 12n is sliver, and the weight percentage of sliver is defined at a range from 65% to 95% with respect to the total weight of each first electrode paste cluster 81; conversely, the first metal component of the first electrode paste clusters 81 disposed on the P-type doping regions 12p is aluminum, and the weight percentage of aluminum is defined at a range from 65% to 95% with respect to the total weight of each first electrode paste cluster 81. In other words, the first metal component is the main composition of the first electrode paste cluster 81 and can be adjusted within the defined percentage interval according to users' requirements. The first electrode paste clusters 81 are disposed on the passivation layer 20 corresponding to the N-type doping regions 12n and the P-type doping regions 12p using screen printing techniques. In some implementation aspects, the first metal component and the weight percentage thereof of the first electrode paste cluster 81 disposed on the N-type doping regions 12n can be the same as or different from those of the first electrode paste cluster 81 disposed on the P-type doping regions 81; for example, the first metal component of the first electrode paste cluster 81 corresponding to the N-type doping regions 12n is silver and the weight percentage of silver is 80%, while the first metal component of the first electrode paste cluster 81 corresponding to the P-type doping regions 12p is silver-aluminum alloy and the weight percentage of the silver-aluminum alloy is 90%, but embodiments are not limited thereto.

The first electrode paste clusters 81 are distantly disposed on the passivation layer 20 in a spot manner and correspond to the N-type doping regions 12n and the P-type doping regions 12p. The distances between the first electrode paste clusters 81 are adjustable according to the measured electric properties.

Please refer to FIG. 2 and FIG. 3B, in which step S05 is enclosing the first electrode paste cluster 81 by a second electrode paste 82 in which the first electrode paste cluster 81 and the second electrode paste 82 are on the same doping region. In this embodiment, the second electrode paste 82 is conductive and includes a second metal component and a second glass component. The second metal component is selected from aluminum, silver, copper and combinations thereof, but embodiments are not limited thereto. The second glass component of the second electrode paste 82 excludes bismuth and lead. In some implementation aspects, the weight percentage of the second metal component is defined at a range from 70% to 97% with respect to the total weight of the second electrode paste 82.

In this embodiment, the second electrode paste 82 is directly formed on the first electrode paste clusters 81 which are already dried but not sintered using screen printing techniques. Alternatively, the second electrode paste 82 is formed on the first electrode paste clusters 81 after the first electrode paste clusters 81 are sintered to form the contacting regions 30. The second electrode paste 82 is bar shaped and electrically connected to all the first electrode paste clusters 81 which are disposed on the same doping region as the second electrode paste 82 being disposed.

Step S06 is heating the first electrode paste clusters 81 to a predetermined temperature. When the temperature is equal to or higher than the predetermined temperature, the first glass component of the first electrode paste cluster 81 and the passivation layer 20 adjacent thereto form an eutectic composition at interfaces therebetween, wherein the eutectic composition has a low melting point. At this moment, since the temperature of the circumstance is higher than the melting point of the eutectic composition, the eutectic composition is in a melting state, thereby allowing the first metal component of the first electrode paste clusters 81 to enter into the passivation layer 20 and to form the contacting regions 30 distributed in a spot manner, so that the first electrode paste clusters 81 contacts with the P-type doping regions 12p or the N-type doping regions 12n below the passivation layer 20 via the contacting regions 30, as shown in FIG. 3C. The contacting regions 30 are electrically connected to the P-type doping regions 12p and the N-type doping regions 12n, respectively. The contacting regions 30 include the first metal component, first glass component and the passivation layer 20. Therefore, after the first electrode paste clusters 81 are disposed on the passivation layer 20 followed with enclosing the first electrode paste clusters 81 by the second electrode paste 82, the aforementioned structure undergoes the sintering procedure; in this step, parts of the first electrode paste clusters 81 including bismuth glass or lead glass enter into the passivation layer 20 to form the contacting regions 30, and the first electrode paste clusters 81 and the second electrode paste 82 form an electronic structure 40, namely, step S07. Based on this, the electricity generated by the back-contact solar cell 100 is collected by the electronic structure 40 through the contacting regions 30, thereby outputting to outside. In this embodiment, the second glass component of the second electrode paste 82 excludes bismuth and lead, so when the first electrode paste clusters 81 and the second electrode paste 82 are heated, the second glass component of the second electrode paste 82 are not carried into the passivation layer 20, so that no contacting regions 30 are formed in the passivation layer 20 below the second electrode paste 82.

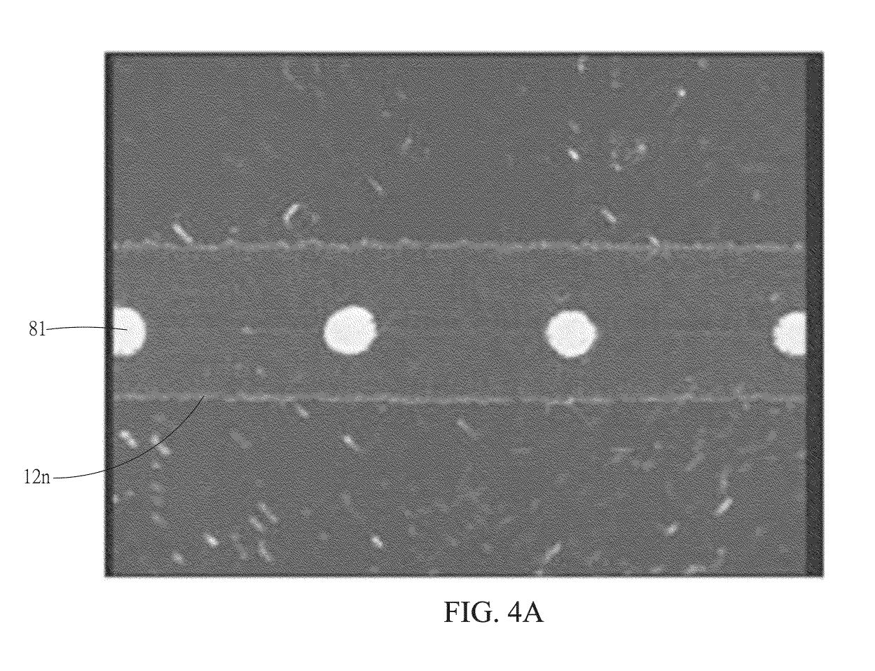

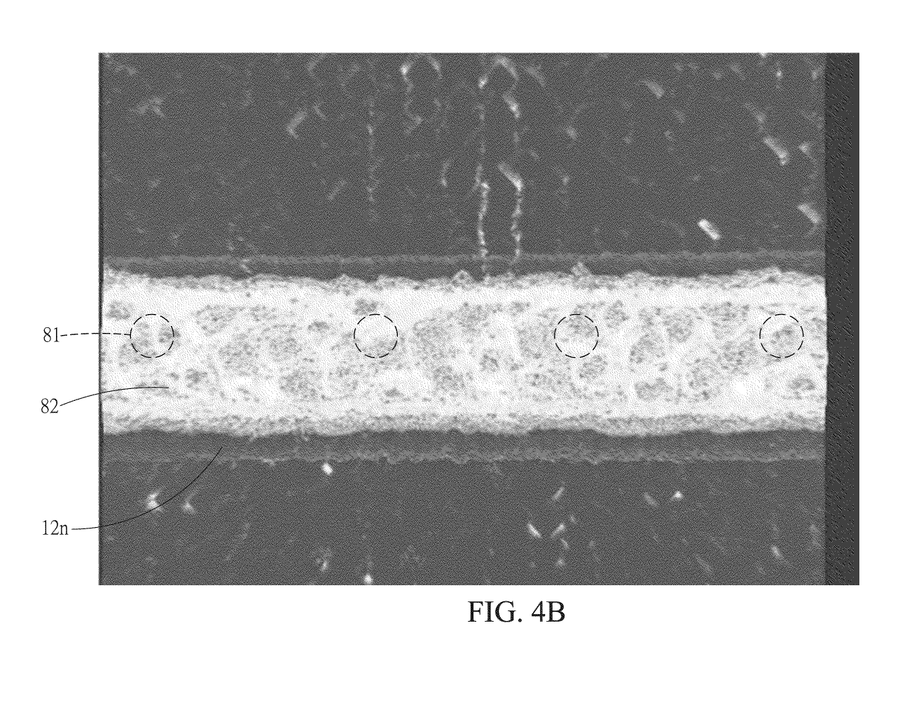

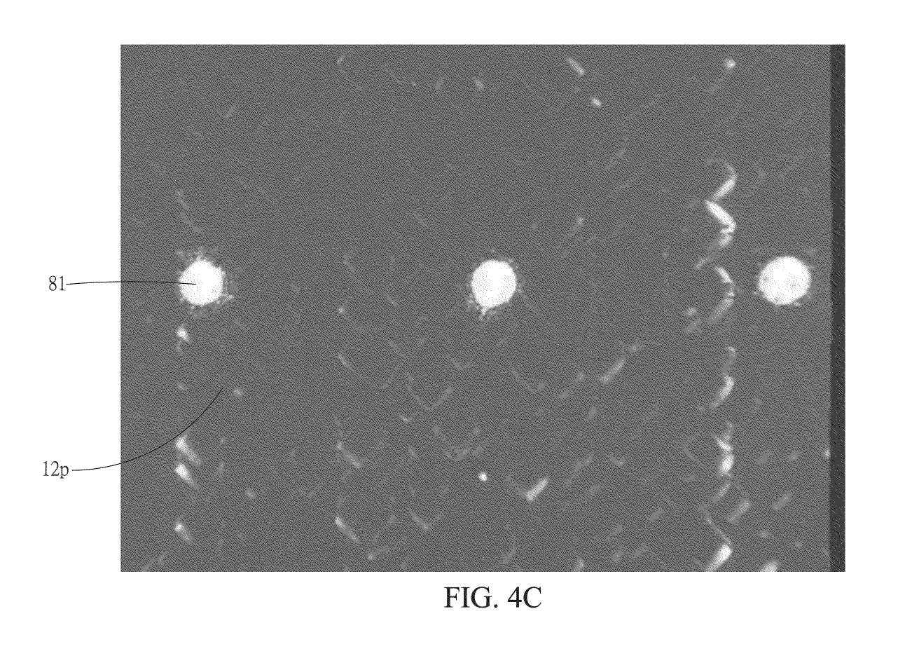

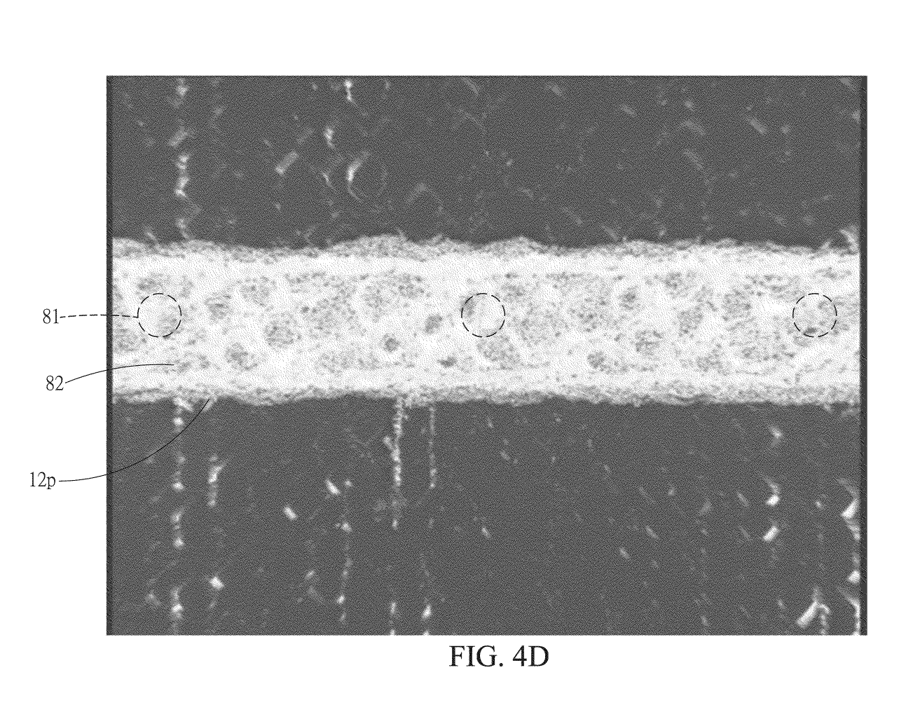

Please refer to FIG. 4A to FIG. 4D, in which upon viewing the first electronic paste clusters 81 and the second electrode paste 82 vertical to the second surface 12, the ratio of the area of the passivation layer 20 covered by the first electrode paste cluster 81 over the area of the passivation layer 20 covered by the second electrode paste 82 and the area of the first electrode paste cluster 81 covered by the second electrode paste 82 (namely, the total area covered by the second electrode paste 82), is defined at the range from 1:1.2 to 1:100. That is, in an overview of the second surface 12 of the substrate 10, the area of the second electrode paste 82 is 1.2 to 100 times as large as the area of the first electrode paste clusters 81.

In some implementation aspects, the substrate 10 provided in step S01 is not roughened, and the first surface 11 of the substrate 10 is a flat surface.

In some implementation aspects, in step S02 further includes a step of forming a first dielectric layer, for example an aluminum oxide layer, on the second surface 12; in step S03 further includes forming a second dielectric layer, for example an aluminum oxide layer or a silicon oxynitride layer, on the second surface 12. Therefore, the first dielectric layer, the passivation layer 20 and the second dielectric layer are sequentially disposed on the second surface 12. Then, in step S04, the first electrode paste clusters 81 are disposed on the second dielectric layer; and in step S05 and S06, parts of the first electrode paste clusters 81 enter into the first dielectric layer, the passivation layer 20 and the second dielectric layer to form the contacting regions 30, and the first electrode paste clusters 81 and the second electrode paste 82 mutually form the electrode structure 40.

Please refer to the enlarged scanning electron microscope images shown in FIG. 4A to FIG. 4D, which illustrate the distribution relationship between the first electrode paste clusters 81 of the contacting regions 30 and the second electrode paste 82 of the electrode structure 40, wherein the first electrode paste clusters 81 of the contacting regions 30 are electrically connected with each other via the second electrode paste 82 of the electrode structure 40. In this embodiment, the second electrode paste 82 of each electrode structure 40 is a continuous line structure, and the first electrode paste clusters 81 of the contacting regions 30 are distributed on the passivation layer 20 in a spot manner and are involved within the aforementioned line structure. It is understood that the first electrode paste clusters 81 and the contacting regions 30 enclosed by the second electrode paste 82 of the same electrode structure 40 correspond to the doping regions with the same conductive property; in other words, the first electrode paste clusters 81 and contacting regions 30 enclosed by the second electrode paste 82 of one electrode structure 40 correspond to the P-type doping regions 12p, and the first electrode paste clusters 81 and contacting regions 30 enclosed by the second electrode paste 82 of another electrode structure 40 correspond to the N-type doping regions 12n. Therefore, the second electrode paste 82 of the electrode structure 40 collects and integrates the first electrode paste clusters 81 of the contacting regions 30 with same conductive property.

Furthermore, in some implementation aspects, the thickness ratio between the passivation layer 20 and the electrode structure 40 is defined at the range from 1:50 to 1:2000.

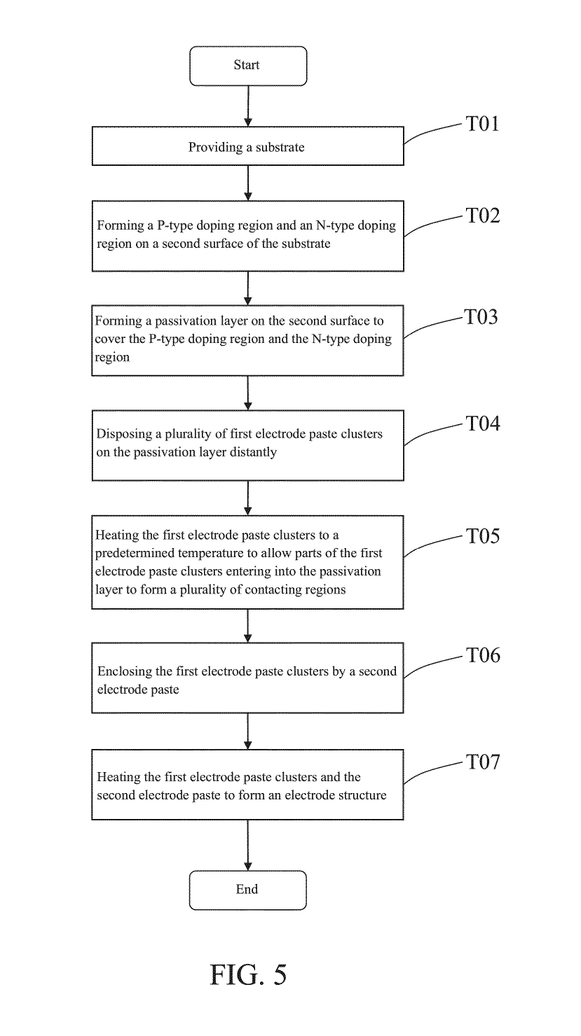

Please refer to FIG. 5, which illustrates a flowchart showing a manufacturing method for back-contact solar cell of a second embodiment of the disclosure. The second embodiment is approximately the same as the first embodiment, except that in this embodiment, after the first electrode paste clusters 81 are disposed distantly on the passivation layer 20 (step T04), the first electrode paste clusters 81 are then heated to be sintered to form the contacting regions 30 (step T05), then the second electrode paste 82 is applied to enclose all of the first electrode paste clusters 81 which are disposed on the same doping region as the second electrode paste 82 being disposed (step T06), lastly, the first electrode paste clusters 81 and the second electrode paste 82 are heated to form the electrode structure 40 (step T07).

As above, by using the manufacturing method for back-contact solar cell of the disclosure, the surfaces of the P-type doping regions (or the N-type doping regions), prevent from being damaged by the laser beams applied in conventional laser opening techniques. Reduction of the surface defects slows down the surface carrier recombination velocity, thereby improving the electricity generation efficiency of the back-contact solar cell. Furthermore, as compared to the conventional process, the manufacturing method for back-contact solar cell of the disclosure has a cheaper cost, a simpler manufacturing process, a higher yield rate, and other advantages.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A manufacturing method for back-contact solar cell, comprising:
providing a substrate, wherein the substrate comprising a first surface and a second surface;
forming a first conductive doping region and a second conductive doping region on the second surface;
forming a passivation layer on the second surface to cover the first conductive doping region and the second conductive doping region;
disposing a plurality of first electrode paste clusters on the passivation layer distantly, wherein the first electrode paste clusters correspond to the first conductive doping region and the second conductive doping region, each first electrode paste cluster comprises a first metal component and a first glass component selected from the group consisting of bismuth glass and lead glass;
enclosing the first electrode paste clusters by a second electrode paste; and
heating the first electrode paste clusters and the second electrode paste to a predetermined temperature, so that a plurality of contacting regions is formed on the passivation layer and the first electrode paste clusters and the second electrode paste form an electrode structure.

2. The manufacturing method for back-contact solar cell according to claim 1, wherein the passivation layer is selected from the group consisting of silicon nitride, silicon oxide, silicon oxynitride, aluminum oxide and combinations thereof.

3. The manufacturing method for back-contact solar cell according to claim 1, wherein the weight percentage of the first metal component is defined at a range from 65% to 95% with respect to the total weight of each first electrode paste cluster.

4. The manufacturing method for back-contact solar cell according to claim 3, wherein the first metal component is selected from the group consisting of aluminum, silver, copper and combinations thereof.

5. The manufacturing method for back-contact solar cell according to claim 1, wherein the second electrode paste comprises a second metal component and a second glass component, the weight percentage of the second metal component is defined at a range from 70% to 97% with respect to the total weight of the second electrode paste, the second glass excludes bismuth and lead.

6. The manufacturing method for back-contact solar cell according to claim 2, wherein the second electrode paste comprises a second metal component and a second glass component, the weight percentage of the second metal component is defined at a range from 70% to 97% with respect to the total weight of the second electrode paste, the second glass excludes bismuth and lead.

7. The manufacturing method for back-contact solar cell according to claim 3, wherein the second electrode paste comprises a second metal component and a second glass component, the weight percentage of the second metal component is defined at a range from 70% to 97% with respect to the total weight of the second electrode paste, the second glass excludes bismuth and lead.

8. The manufacturing method for back-contact solar cell according to claim 4, wherein the second electrode paste comprises a second metal component and a second glass component, the weight percentage of the second metal component is defined at a range from 70% to 97% with respect to the total weight of the second electrode paste, the second glass excludes bismuth and lead.

9. The manufacturing method for back-contact solar cell according to claim 1, wherein a ratio of a first area covered by the first electrode paste clusters over a second area covered by the second electrode paste is defined at the range from 1:1.2 to 1:100.

10. The manufacturing method for back-contact solar cell according to claim 2, wherein a ratio of a first area covered by the first electrode paste clusters over a second area covered by the second electrode paste is defined at the range from 1:1.2 to 1:100.

11. The manufacturing method for back-contact solar cell according to claim 3, wherein a ratio of a first area covered by the first electrode paste clusters over a second area covered by the second electrode paste is defined at the range from 1:1.2 to 1:100.

12. The manufacturing method for back-contact solar cell according to claim 4, wherein a ratio of a first area covered by the first electrode paste clusters over a second area covered by the second electrode paste is defined at the range from 1:1.2 to 1:100.

13. The manufacturing method for back-contact solar cell according to claim 1, further comprising forming a first dielectric layer between the passivation layer and the second surface.

14. The manufacturing method for back-contact solar cell according to claim 2, further comprising forming a first dielectric layer between the passivation layer and the second surface.

15. The manufacturing method for back-contact solar cell according to claim 3, further comprising forming a first dielectric layer between the passivation layer and the second surface.

16. The manufacturing method for back-contact solar cell according to claim 4, further comprising forming a first dielectric layer between the passivation layer and the second surface.

17. The manufacturing method for back-contact solar cell according to claim 1, further comprising forming a second dielectric layer on the passivation layer.

18. The manufacturing method for back-contact solar cell according to claim 2, further comprising forming a second dielectric layer on the passivation layer.

19. The manufacturing method for back-contact solar cell according to claim 3, further comprising forming a second dielectric layer on the passivation layer.

20. The manufacturing method for back-contact solar cell according to claim 4, further comprising forming a second dielectric layer on the passivation layer.

21. A manufacturing method for back-contact solar cell, comprising:
providing a substrate, wherein the substrate comprises a first surface and a second surface;
forming a first conductive doping region and a second conductive doping region on the second surface;
forming a passivation layer on the second surface to cover the first conductive doping region and the second conductive doping region;
disposing a plurality of first electrode paste clusters on the passivation layer distantly, wherein the first electrode paste clusters corresponds to the first conductive doping region and the second conductive doping region, each first electrode paste cluster comprises a first metal component and a first glass component selected from the group consisting of bismuth glass and lead glass;
heating the first electrode paste clusters to a predetermined temperature, so that the first metal component, the first glass component and the passivation layer contacted to the first electrode paste clusters form a plurality of contacting regions;
enclosing the first electrode paste clusters by a second electrode paste; and
heating the first electrode paste clusters and the second electrode paste to form an electrode structure.

22. The manufacturing method for back-contact solar cell according to claim 21, wherein the passivation layer is selected from the group consisting of silicon nitride, silicon oxide, silicon oxynitride, aluminum oxide and combinations thereof.

23. The manufacturing method for back-contact solar cell according to claim 21, wherein the weight percentage of the first metal component is defined at a range from 65% to 95% with respect to the total weight of each first electrode paste cluster.

24. The manufacturing method for back-contact solar cell according to claim 23, wherein the first metal component is selected from the group consisting of aluminum, silver, copper and combinations thereof.

25. The manufacturing method for back-contact solar cell according to claim 21, wherein the second electrode paste comprises a second metal component and a second glass component, the weight percentage of the second metal component is defined at a range from 70% to 97% with respect to the total weight of the second electrode paste, the second glass excludes bismuth and lead.

26. The manufacturing method for back-contact solar cell according to claim 22, wherein the second electrode paste comprises a second metal component and a second glass component, the weight percentage of the second metal component is defined at a range from 70% to 97% with respect to the total weight of the second electrode paste, the second glass excludes bismuth and lead.

27. The manufacturing method for back-contact solar cell according to claim 23, wherein the second electrode paste comprises a second metal component and a second glass component, the weight percentage of the second metal component is defined at a range from 70% to 97% with respect to the total weight of the second electrode paste, the second glass excludes bismuth and lead.

28. The manufacturing method for back-contact solar cell according to claim 24, wherein the second electrode paste comprises a second metal component and a second glass component, the weight percentage of the second metal component is defined at a range from 70% to 97% with respect to the total weight of the second electrode paste, the second glass excludes bismuth and lead.

29. The manufacturing method for back-contact solar cell according to claim 21, wherein a ratio of a first area covered by the first electrode paste clusters over a second area covered by the second electrode paste is defined at the range from 1:1.2 to 1:100.

30. The manufacturing method for back-contact solar cell according to claim 22, wherein a ratio of a first area covered by the first electrode paste clusters over a second area covered by the second electrode paste is defined at the range from 1:1.2 to 1:100.

31. The manufacturing method for back-contact solar cell according to claim 23, wherein a ratio of a first area covered by the first electrode paste clusters over a second area covered by the second electrode paste is defined at the range from 1:1.2 to 1:100.

32. The manufacturing method for back-contact solar cell according to claim 24, wherein a ratio of a first area covered by the first electrode paste clusters over a second area covered by the second electrode paste is defined at the range from 1:1.2 to 1:100.

33. The manufacturing method for back-contact solar cell according to claim 21, further comprising forming a first dielectric layer between the passivation layer and the second surface.

34. The manufacturing method for back-contact solar cell according to claim 22, further comprising forming a first dielectric layer between the passivation layer and the second surface.

35. The manufacturing method for back-contact solar cell according to claim 23, further comprising forming a first dielectric layer between the passivation layer and the second surface.

36. The manufacturing method for back-contact solar cell according to claim 24, further comprising forming a first dielectric layer between the passivation layer and the second surface.

37. The manufacturing method for back-contact solar cell according to claim 21, further comprising forming a second dielectric layer on the passivation layer.

38. The manufacturing method for back-contact solar cell according to claim 22, further comprising forming a second dielectric layer on the passivation layer.

39. The manufacturing method for back-contact solar cell according to claim 23, further comprising forming a second dielectric layer on the passivation layer.

40. The manufacturing method for back-contact solar cell according to claim 24, further comprising forming a second dielectric layer on the passivation layer.

41. A back-contact solar cell, comprising:
a substrate, comprising a first surface and a second surface, wherein the first surface is a light incident surface, and the second surface comprises a first conductive doping region and a second conductive doping region;
a passivation layer, disposed on the second surface to cover the first conductive doping region and the second conductive doping region;
a plurality of contacting regions, distantly disposed in the passivation layer and electrically connected to the first conductive doping region and the second conductive doping region respectively, wherein each contacting region comprises a metal component, a glass component and the passivation layer, the glass component is selected from the group consisting of bismuth glass and lead glass, the passivation layer is selected from the group consisting of silicon nitride, silicon oxide, silicon oxynitride and aluminum oxide; and
a plurality of electrode structures, electrically connected to the contacting regions.

42. The back-contact solar cell according to claim 41, wherein the weight percentage of the metal component is defined at a range from 75% to 95% with respect to the total weight of each contacting region.

43. The back-contact solar cell according to claim 42, wherein the metal component is selected from the group consisting of aluminum, silver, copper and combinations thereof.

44. The back-contact solar cell according to claim 41, wherein the thickness ratio between the passivation layer and the electrode structures is defined at the range from 1:50 to 1:2000.

45. The back-contact solar cell according to claim 42, wherein the thickness ratio between the passivation layer and the electrode structures is defined at the range from 1:50 to 1:2000.

46. The back-contact solar cell according to claim 43, wherein the thickness ratio between the passivation layer and the electrode structures is defined at the range from 1:50 to 1:2000.

47. The back-contact solar cell according to claim 41, wherein the first surface further comprises an anti-reflection layer.

48. The back-contact solar cell according to claim 42, wherein the first surface further comprises an anti-reflection layer.

49. The back-contact solar cell according to claim 43, wherein the first surface further comprises an anti-reflection layer.

50. The back-contact solar cell according to claim 41, further comprising a first dielectric layer, disposed between the passivation layer and the second surface.

51. The back-contact solar cell according to claim 42, further comprising a first dielectric layer, disposed between the passivation layer and the second surface.

52. The back-contact solar cell according to claim 43, further comprising a first dielectric layer, disposed between the passivation layer and the second surface.

53. The back-contact solar cell according to claim 41, further comprising a second dielectric layer, disposed between the passivation layer and the electrode structures.

54. The back-contact solar cell according to claim 42, further comprising a second dielectric layer, disposed between the passivation layer and the electrode structures.

55. The back-contact solar cell according to claim 43, further comprising a second dielectric layer, disposed between the passivation layer and the electrode structures.

56. The back-contact solar cell according to claim 41, wherein the passivation layer is selected from the group consisting of silicon nitride, silicon oxide, silicon oxynitride, aluminum oxide and combinations thereof.

57. The back-contact solar cell according to claim 42, wherein the passivation layer is selected from the group consisting of silicon nitride, silicon oxide, silicon oxynitride, aluminum oxide and combinations thereof.

58. The back-contact solar cell according to claim 43, wherein the passivation layer is selected from the group consisting of silicon nitride, silicon oxide, silicon oxynitride, aluminum oxide and combinations thereof.
